(19) United States
(12) Patent Application Publication
(10) Pub. No.: US 2014/0080317 A1
(43) Pub. Date: Mar. 20, 2014

(54) MEHOD OF MANUFACTURING A SEMICONDUCTOR DEVICE AND SUBSTRATE PROCESSING APPARATUS

(71) Applicant: HITACHI KOKUSAI ELECTRIC INC., Tokyo (JP)

(72) Inventors: Yukinao KAGA, Toyama-shi (JP); Masanori SAKAI, Toyama-shi (JP); Takashi YOKOGAWA, Toyama-shi (JP)

(73) Assignee: HITACHI KOKUSAI ELECTRIC INC., Tokyo (JP)

(21) Appl. No.: 14/031,734

(22) Filed: Sep. 19, 2013

(30) Foreign Application Priority Data
Sep. 20, 2012 (JP) 2012-207425

(51) Int. Cl. H01L 21/02

(52) U.S. Cl. CPC H01L 21/02186
USPC 438/775

(57) ABSTRACT

A stress of a film formed on a substrate can be reduced. A method of manufacturing a semiconductor device includes: forming a film on the substrate by supplying a process gas to the substrate while heating the substrate to a first temperature; controlling a stress to the film by changing a stress value of the film formed on the substrate, by supplying a plasma-excited process gas to the substrate while changing a temperature of the substrate to a second temperature different from the first temperature; and unloading the substrate from the processor chamber.

### BACKGROUND

1. Technical Field

The present invention relates to a method of manufacturing a semiconductor device and a substrate processing apparatus.

2. Related Art

As a semiconductor device manufacturing process, there is a process of forming a film on a heated substrate.

### CITATION LIST

### Patent Literature

Patent Literature 1: JP 2011-168881 A

### SUMMARY

In a case where a substrate and a film have different thermal expansion coefficients, when a film is formed on a heated substrate and then the temperature thereof is dropped to a room temperature, a stress may be generated in the film. The film stress may cause a film peel-off, a film crack, a substrate warpage, or the like, and may cause a degradation of the electrical characteristics of a semiconductor device, a reliability degradation, a production yield degradation, a throughput degradation, or the like.

A main object of the present invention is to provide a method of manufacturing a semiconductor device and a substrate processing apparatus, which can reduce a film stress.

According to an aspect of the present invention, there is provided a method of manufacturing a semiconductor device including:

forming a film on a substrate by supplying a process gas to the substrate while heating the substrate to a first temperature; and

controlling a stress to the film by changing a stress value of the film formed on the substrate, by supplying a plasma-excited process gas to the substrate while changing a temperature of the substrate to a second temperature different from the first temperature.

According to another aspect of the present invention, there is provided a method of manufacturing a semiconductor device including:

forming a film on a substrate by supplying a first process gas and a second process gas, wherein the second process gas is supplied by separated temporary pulse while the first process gas is supplied; and

controlling a stress to the film by changing a stress value of the film.

According to another aspect of the present invention, there is provided a substrate processing method including:

forming a film on a substrate by supplying a process gas to the substrate while heating the substrate to a first temperature; and

controlling a stress to the film by changing a stress value of the film, by supplying a plasma-excited process gas to the substrate while changing a temperature of the substrate to a second temperature different from the first temperature.

According to another aspect of the present invention, there is provided a substrate processing apparatus including:

a process chamber configured to accommodate a substrate;

a heating system configured to heat the substrate;

a process gas supply system configured to a plurality of types of process gases to the substrate;

a plasma generating system configured to generate plasma for plasma-exciting at least one of the plurality of types of process gases; and

a control unit configured to control the heating system, the process gas supply system, and the plasma generating system to form a film on the substrate by supplying a plurality of types of process gases to the process chamber while heating the substrate to a first temperature, and to control stress to the film by changing a stress value of the film by supplying a plasma-excited process gas to the substrate while changing a temperature of the substrate from the first temperature to a second temperature.

According to another aspect of the present invention, there is provided a program for causing a computer to execute:

forming a film on a substrate inside a process chamber of a substrate processing apparatus by supplying a process gas to the substrate while heating the substrate to a first temperature; and

controlling a stress to change a stress value of the film formed on the substrate, by supplying a plasma-excited process gas to the substrate while changing a temperature of the substrate to a second temperature different from the first temperature.

The present invention provides a method of manufacturing a semiconductor device and a substrate processing apparatus, which can reduce a film stress.

### BRIEF DESCRIPTION OF THE DRAWINGS

FIG. 1 is a schematic vertical cross-sectional view illustrating a substrate processing apparatus according to an exemplary embodiment of the present invention;

FIG. 2 is a schematic horizontal cross-sectional view taken along a line A-A of FIG. 1;

FIG. 3 is a schematic diagram illustrating a controller of a substrate processing apparatus according to an exemplary embodiment of the present invention;

FIG. 4 is a flow chart illustrating a titanium nitride (TiN) film manufacturing process according to an exemplary embodiment of the present invention;

FIG. 5 is a timing chart illustrating a TiN film manufacturing process according to an exemplary embodiment of the present invention;

FIG. 6 is a timing chart illustrating an example of a stress control process according to an exemplary embodiment of the present invention;

FIG. 7 is a timing chart illustrating another example of a stress control process according to an exemplary embodiment of the present invention;

FIG. 8 is a diagram illustrating a film stress in a case where a stress control process is performed and a film stress in case where a stress control process is not performed; and

FIG. 9 is a diagram illustrating a relation between the deposition temperature and the resistivity of a TiN film.

### DETAILED DESCRIPTION

Hereinafter, exemplary embodiments of the present invention will be described with reference to the drawings.

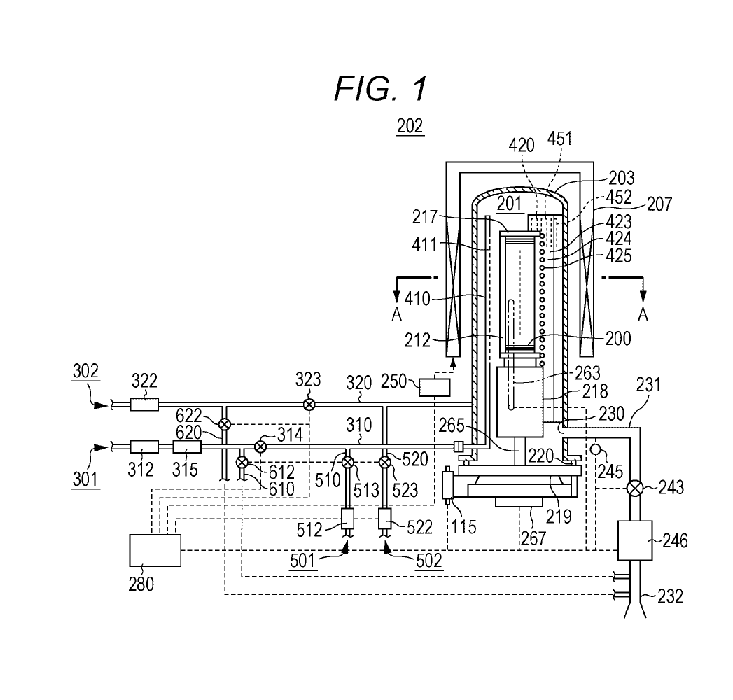

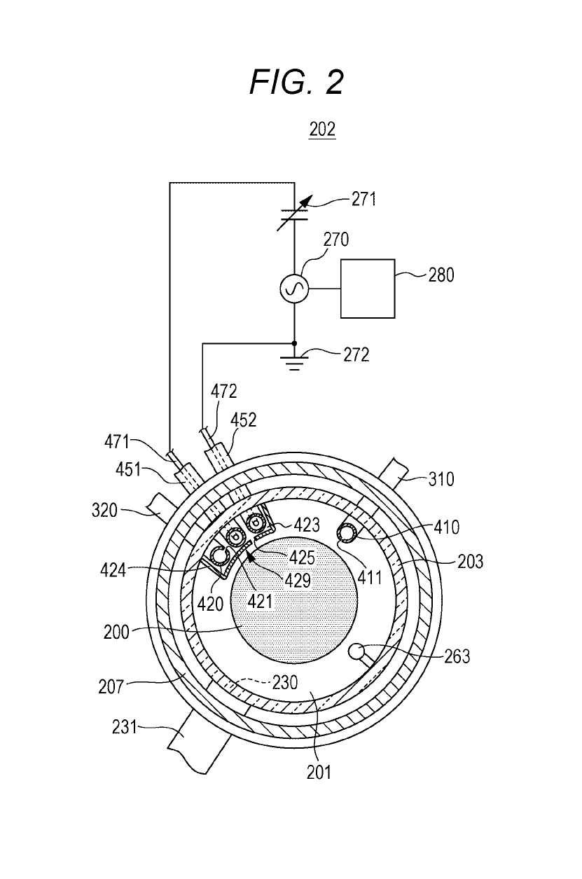

First, a process furnace 202 used in a substrate processing apparatus used suitably in each of the exemplary embodiments of the present invention will be described with reference to FIGS. 1 and 2. The substrate processing apparatus is provided as an example of a semiconductor device manufacturing apparatus used to manufacture a semiconductor device.

Referring to FIGS. 1 and 2, the process furnace 202 is provided with a heater 207 that is a heating device (heating unit) for heating a wafer 200. The heater 207 includes a cylindrical insulating member with a closed top portion and a plurality of heater wires, and has a unit configuration in which the heater wires are provided for the insulating member. A reaction tube 203 formed of quartz to process the wafer 200 is provided concentrically with the heater 207 inside the heater 207.

As a furnace port cover for air-tightly closing a bottom opening of the reaction tube 203, a seal cap 219 is provided under the reaction tube 203. The seal cap 219 abuts the bottom end of the reaction tube 203 from a vertically lower side. For example, the seal cap 219 is formed of a metal such as stainless steel and has a disk shape. An air-tight member (hereinafter referred to as O-ring) 220 is disposed between the top surface of the seal cap 219 and a circular flange provided at a lower opening end of the reaction tube 203, such that they are air-tightly sealed therebetween. A process chamber 201 is formed at least by the reaction tube 203 and the seal cap 219.

A boat support 218 is provided on the seal cap 219 to support a boat 217. The boat support 218 is formed of, for example, a heat-resistant material such as quartz or silicon carbide. The boat support 218 functions as an insulating portion and supports the boat 217. The boat 217 is erected on the boat support 218. The boat 217 is formed of, for example, a heat-resistant material such as quartz or silicon carbide. The boat 217 includes a bottom plate fixed to the boat support 218 and a top plate disposed thereon, and has a configuration in which a plurality of supporters 212 are installed between the bottom plate and the top plate. A plurality of wafers 200 is held in the boat 217. The plurality of wafers 200 holds a horizontal posture while being spaced apart from each other by a predetermined distance, and are supported by the supporters 212 of the boat 217, which are loaded in multi-stage in the tube axis direction of the reaction tube 203, with their centers aligned with each other.

A boat rotation mechanism 267 rotating the boat 217 is provided on the opposite side of the process chamber 201 of the seal cap 219. A rotation shaft 265 of the boat rotation mechanism 267 is connected to the boat support 218 through the seal cap 219. The boat rotation mechanism 267 rotates the wafer 200 by rotating the boat 217 with the boat support 218 interposed therebetween.

The seal cap 219 is vertically elevated by a boat elevator 115 provided as an elevating mechanism outside the reaction tube 203, so that the boat 217 can be loaded/unloaded into/from the process chamber 201.

In the process furnace 202, a plurality of wafers 200 to be batch-processed are stacked in multi-stage on the boat 217, the boat 217 is supported by the boat support 218 and loaded into the process chamber 201, and the heater 207 heats the wafer 200 loaded into the process chamber 201 to a predetermined temperature.

Referring to FIGS. 1 and 2, two gas supply pipes 310 and 320 are connected to the reaction tube 203 to supply a process gas (raw material gas or reaction gas).

Nozzles 410 and 420 are provided inside the process chamber 201. The nozzles 410 and 420 are provided to penetrate a bottom portion of the reaction tube 203. A gas supply pipe 310 is connected to the nozzle 410, and a gas supply pipe 320 is connected to the nozzle 420.

Sequentially from the upstream side, the gas supply pipe 310 is provided with a mass flow controller 312 that is a flow control device (flow control unit), a vaporizer 315 that is a vaporizing unit, and a valve 314 that is an opening/closing valve.

A downstream side end of the gas supply pipe 310 is connected to an end of the nozzle 410. In a circular arc-shaped space between the wafer 200 and the inner wall of the reaction tube 203, the nozzle 410 protrudes upward in the stack direction of the wafers 200 from the bottom to the top of the inner wall of the reaction tube 203. That is, the nozzle 410 is provided along a wafer arrangement region, in which the wafers 200 are arranged, in a region horizontally surrounding the wafer arrangement region, beside the wafer arrangement region. The nozzle 410 includes an L-shaped long nozzle, wherein a horizontal portion thereof is provided to penetrate the lower sidewall of the reaction tube 203, and a vertical portion thereof is provided to protrude at least from one end side to the other end side of the wafer arrangement region. A plurality of gas supply holes 411 are provided at the side surface of the nozzle 410 to supply a process gas. The gas supply holes 411 are opened toward the center of the reaction tube 203. The gas supply holes 411 have different opening areas from the bottom to the top, and are provided at regular pitches.

Also, a valve 612 and a vent line 610 connected to an exhaust pipe 232, which will be described later, are provided at the gas supply pipe 310 between the vaporizer 315 and the valve 314. When a process gas is not supplied to the process chamber 201, the process gas is supplied to the vent line 610 through the valve 612.

A first gas supply system (raw material gas supply system or first process gas supply system) 301 mainly includes the gas supply pipe 310, the mass flow controller 312, the vaporizer 315, the valve 314, the nozzle 410, the vent line 610, and the valve 612.

Also, at the gas supply pipe 310, a carrier gas supply pipe 510 is connected to the downstream side of the valve 314 to supply a carrier gas (inert gas). The carrier gas supply pipe 510 is provided with a mass flow controller 512 and a valve 513. A first carrier gas supply system (first inert gas supply system) 501 mainly includes the carrier gas supply pipe 510, the mass flow controller 512, and the valve 513.

Sequentially from the upstream side, the gas supply pipe 320 is provided with a mass flow controller 322 that is a flow control device (flow control unit), and a valve 323 that is an opening/closing valve.

A downstream side end of the gas supply pipe 320 is connected to an end of the nozzle 420. The nozzle 420 is provided inside a buffer chamber 423 that is a gas dispersion space (discharge chamber or discharge space). Electrode protecting tubes 451 and 452 are provided inside the buffer chamber 423. The nozzle 420, the electrode protecting tube 451, and the electrode protecting tube 452 are disposed inside the buffer chamber 423 in this order.

The buffer chamber 423 is formed by a buffer chamber wall 424 and the inner wall of the reaction tube 203. In a circular arc-shaped space between the wafer 200 and the inner wall of the reaction tube 203, the buffer chamber wall 424 is provided along the stack direction of the wafers 200 from the bottom to the top of the inner wall of the reaction tube 203. A plurality of gas supply holes 425 are provided at a wall of the buffer chamber wall 424, which is adjacent to the wafer 200, to supply a gas. The gas supply holes 425 are provided between the electrode protecting tube 451 and the electrode protecting tube 452. The gas supply holes 425 are opened toward the center of the reaction tube 203. The gas supply holes 425 are provided from the bottom to the top of the reaction tube 203 at regular pitches, and have the same opening area.

At one end side of the buffer chamber 423, the nozzle 420 protrudes upward in the stack direction of the wafers 200 from the bottom to the top of the inner wall of the reaction tube 203. The nozzle 420 includes an L-shaped long nozzle, wherein a horizontal portion thereof is provided to penetrate the lower sidewall of the reaction tube 203, and a vertical portion thereof is provided to protrude at least from one end side to the other end side of the wafer arrangement region. A plurality of gas supply holes 421 are provided at the side surface of the nozzle 420 to supply a gas. The gas supply holes 421 are opened toward the center of the buffer chamber 423. Like the gas supply holes 425 of the buffer chamber 423, the gas supply holes 421 are provided from the bottom to the top of the reaction tube 203. When the pressure difference between the buffer chamber 423 and the nozzle 420 is small, the gas supply holes 421 have the same opening area and the same pitch from the upstream side (bottom side) to the downstream side (top side). On the other hand, when the pressure difference between the buffer chamber 423 and the nozzle 420 is large, the gas supply holes 421 have different opening areas or pitches that sequentially decrease from the upstream side to the downstream side.

In this embodiment, by controlling the opening areas or pitches of the gas supply holes 421 of the nozzle 420 from the upstream side to the downstream side as described above, a substantially same amount of gas is ejected from each of the gas supply holes 421 although there is a speed difference therebetween. The gas ejected from each of the gas supply holes 421 is introduced into the buffer chamber 423, and then the gas speed difference in the buffer chamber 423 is equalized.

That is, the gas ejected from each of the gas supply holes 421 of the nozzle 420 into the buffer chamber 423 is ejected from the gas supply hole 425 of the buffer chamber 423 into the process chamber 201 after the particle speed of each gas is reduced in the buffer chamber 423. Accordingly, the gas ejected from each of the gas supply holes 421 of the nozzle 420 into the buffer chamber 423 is ejected from each of the gas supply holes 425 of the buffer chamber 423 into the process chamber 201 at a uniform flow rate and speed.

Also, a valve 622 and a vent line 620 connected to the exhaust pipe 232, which will be described later, are provided at the gas supply pipe 320 between the valve 323 and the mass flow controller 322.

A second gas supply system (reaction gas supply system, improved gas supply system, or second process gas supply system) 302 mainly includes the gas supply pipe 320, the mass flow controller 322, the valve 323, the nozzle 420, the buffer chamber 423, the vent line 620, and the valve 622.

Also, at the gas supply pipe 320, a carrier gas supply pipe 520 is connected to the downstream side of the valve 323 to supply a carrier gas (inert gas). The carrier gas supply pipe 520 is provided with a mass flow controller 522 and a valve 523. A second carrier gas supply system (second inert gas supply system) 502 mainly includes the carrier gas supply pipe 520, the mass flow controller 522, and the valve 523.

In the gas supply pipe 320, the flow rate of the process gas is controlled at the mass flow controller 322.

When the process gas is not supplied to the process chamber 201, the valve 323 is closed and the valve 622 is opened to flow the process gas through the valve 622 into the vent line 620.

When the process gas is supplied to the process chamber 201, the valve 622 is closed and the valve 323 is opened to supply the process gas to the gas supply pipe 320 downstream side of the valve 323. On the other hand, the carrier gas is flow-controlled at the mass flow controller 522 and is supplied from the carrier gas supply pipe 520 through the valve 523, and the process gas joins with the carrier gas at the downstream side of the valve 323 and is supplied to the process chamber 201 through the nozzle 420 and the buffer chamber 423.

Inside the buffer chamber 423, a rod-like shape type (a thin and long bar-type) electrode 471 and a rod-like shape type (a thin and long bar-type) electrode 472 are installed in the stack direction of the wafers 200 from the bottom to the top of the reaction tube 203. The electrode 471 and the electrode 472 are provided in parallel to the nozzle 420. The electrode 471 and the electrode 472 are protected by being covered with the electrode protecting tubes 451 and 452 from the top to the bottom, respectively. The electrode 471 is connected to a radio frequency (RF) power supply 270 through a matcher 271, and the electrode 472 is connected to a ground 272 that is a reference potential. Accordingly, plasma is generated in a plasma generation region between the electrode 471 and the electrode 472. A plasma generating mechanism (a plasma generating system) 429 mainly includes the electrode 471, the electrode 472, the electrode protecting tube 451, the electrode protecting tube 452, the buffer chamber 423, and the gas supply hole 425. As a plasma generator (plasma generating unit), a plasma source mainly includes the electrode 471, the electrode 472, the electrode protecting tube 451, and the electrode protecting tube 452. Also, the plasma source may further include the matcher 271 and the RF power supply 270. The plasma source functions as an activating mechanism (plasma generating system) that activates a gas in plasma. The buffer chamber 423 functions as a plasma generating chamber.

The electrode protecting tube 451 and the electrode protecting tube 452 are inserted into the buffer chamber 423, at the height adjacent to the bottom of the boat support 218, through through-holes (not illustrated) provided at the reaction tube 203, respectively.

The electrode protecting tube 451 and the electrode protecting tube 452 may be inserted into the buffer chamber 423 while the electrode 471 and the electrode 472 are isolated from the atmosphere of the buffer chamber 423. When the insides of the electrode protecting tubes 451 and 452 have the same atmosphere as the external (atmospheric) air, the electrodes 471 and 472 inserted respectively into the electrode protecting tubes 451 and 452 are oxidized by the heat generated by the heater 207. Thus, an inert gas purge mechanism (not illustrated) is provided inside the electrode protecting tubes 451 and 452 to charge or purge an inert gas such as nitrogen and suppress an oxygen density sufficiently, thereby preventing the oxidization of the electrodes 471 and 472.

Also, plasma generated in this embodiment is referred to as a remote plasma method. As for the remote plasma method, plasma generated between the electrodes is conveyed to a process target surface by a gas flow to perform plasma processing. In this embodiment, since two electrodes 471 and 472 are accommodated in the buffer chamber 423, ions damaging the wafer 200 hardly leak into the process chamber 201 outside the buffer chamber 423. Also, an electric field is generated to surround the two electrodes 471 and 472 (that is, to surround the electrode protecting tubes 451 and 452 accommodated respectively in the two electrodes 471 and 472), and plasma is generated. An active species included in plasma is supplied from the circumference of the wafer 200 through the gas supply hole 425 of the buffer chamber 423 to the center of the wafer 200. Also, in the case of a vertical batch apparatus in which a plurality of wafers 200 are stacked with the main surface thereof set to be parallel to the horizontal plane as in this embodiment, since the buffer chamber 423 is disposed at the inner wall surface of the reaction tube 203, that is, at a position close to the wafer 200 to be processed, the generated active species is not deactivated and easily reaches the surface of the wafer 200.

In this embodiment, a plasma source mainly includes the electrode 471, the electrode 472, the electrode protecting tube 451, and the electrode protecting tube 452. Also, the plasma source may further include the matcher 271 and the RF power supply 270.

Referring to FIGS. 1 and 2, an exhaust port 230 is provided at a bottom portion of the reaction tube 203. The exhaust port 230 is connected to an exhaust pipe 231. The exhaust port 230 and the gas supply hole 411 of the nozzle 410 are disposed at opposite positions (180° opposite sides) with the wafer 200 interposed therebetween.

In this manner, in a gas supply method according to this embodiment, a gas is carried through the inner wall of the reaction tube 203, the nozzle 410 disposed in a circular arc-shaped vertically-long space defined by the ends of the plurality of loaded wafers 200, and the nozzle 420 disposed in the buffer chamber 423; the gas is first ejected at the neighborhood of the wafer 200 into the reaction tube 203 from the gas supply hole 411 opened to the nozzle 410 and the gas supply hole 425 opened to the buffer chamber 423; and the main gas flow in the reaction tube 203 is set to have a direction parallel to the surface of the wafer 200, that is, the horizontal direction. By this configuration, the gas can be uniformly supplied to each wafer 200, and the film thickness of a thin film formed at each wafer 200 can be equalized. Also, a gas left after the reaction flows toward an exhaust port, that is, an exhaust pipe 231, which will be described later. However, the flow direction of the left gas is determined suitably according the position of the exhaust port, and is not limited to the vertical direction.

Referring to FIGS. 1 and 2, an exhaust pipe 231 exhausting an atmosphere inside the process chamber 201 is connected to the exhaust port 230 provided at the bottom portion of the reaction tube 203. Through a pressure sensor 245 as a pressure detector (pressure detecting unit) detecting the pressure inside the process chamber 201 and an auto pressure controller (APC) valve 243 as a pressure controller (pressure control unit), a vacuum pump 246 as a vacuum exhaust device is connected to the exhaust pipe 231 such that the pressure inside the process chamber 201 is vacuum-exhausted to a predetermined pressure (vacuum degree). The exhaust pipe 232 at the downstream side of the vacuum pump 246 is connected to a waste gas processing device (not illustrated) or the like. Also, the APC valve 243 may be opened/closed to perform vacuum exhaustion/vacuum exhaustion stop in the process chamber 201. The APC valve 243 is an opening/closing valve that is configured to control a valve opening degree to control a conductance and the pressure inside the process chamber 201. An exhaust system mainly includes the exhaust pipe 231, the APC valve 243, and the pressure sensor 245. Also, the exhaust system may further include the vacuum pump 246 and the waste gas processing device.

A temperature sensor 263 as a temperature detector is provided inside the reaction tube 203. By adjusting the power supplied to the heater 207 based on temperature information detected by the temperature sensor 263, the temperature inside the process chamber 201 is set to have a desired temperature distribution. The temperature sensor 263 has a L-shaped structure. The temperature sensor 263 is introduced through a manifold 209 and is provided along the inner wall of the reaction tube 203. A heating system mainly includes the temperature sensor 263 and the heater 207.

The boat 217 is provided at a center portion inside the reaction tube 203. By the boat elevator 115, the boat 217 is elevated on (loaded/unloaded into/from) the reaction tube 203. When the boat 217 is loaded into the reaction tube 203, the bottom end of the reaction tube 203 is air-tightly sealed with the seal cap 219 through the O-ring 220. The boat 217 is supported by the boat support 218. In order to improve the processing uniformity, the boat rotation mechanism 267 is driven to rotate the boat 217 supported by the boat support 218.

As an example related to the above configuration, for example, a titanium (Ti)-containing raw material (titanium tetrachloride (TiCl₄)) is introduced as a raw material gas (first process gas) into the gas supply pipe 310. As a reaction gas (second process gas), a nitrogen (N)-containing gas, for example, ammonia (NH₃) (i.e., a nitride raw material) is introduced into the gas supply pipe 320.

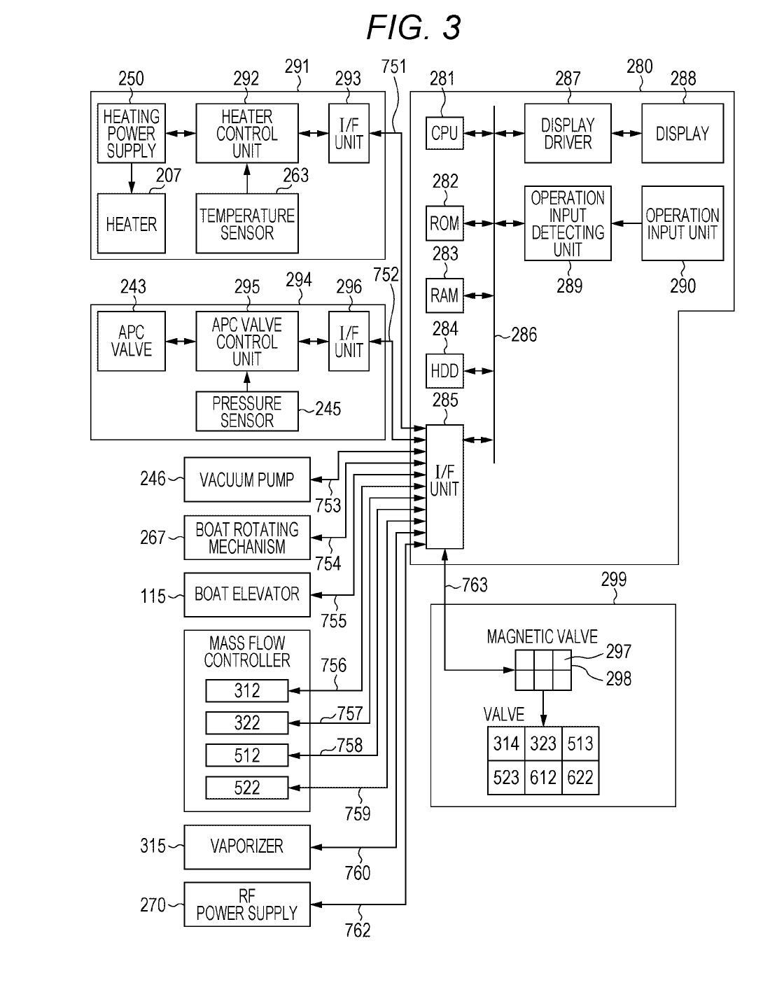

Referring to FIG. 3, a controller 280 includes: a display 288 displaying operation menus or the like; and an operation input unit 290 including a plurality of keys to input various information or operation instructions. Also, the controller 280 includes: a central processing unit (CPU) 281 that manages an overall operation of a substrate processing apparatus 101; a read only memory (ROM) 282 as a memory device that stores various programs including a control program, a random access memory (RAM) 283 that temporarily stores various data; a hard disk drive (HDD) 284 that stores and retains various data; a display driver 287 that controls the display of various information on the display 288 and receives operation information from the display 288; an operation input detecting unit 289 that detects an operation state on the operation input unit 290; and a communication interface (I/F) unit 285 that communicates various information with respective members, such as a temperature control unit 291 (which will be described later), a pressure control unit 294 (which will be described later), the vacuum pump 246, the boat rotation mechanism 267, the boat elevator 115, the mass flow controllers 312, 322, 512 and 522, the vaporizer 315, and a valve control unit 299 (which will be described later). Herein, the ROM 282 readably stores a control program controlling an operation of the substrate processing apparatus, and a process recipe describing a process of substrate processing that will be described later. Also, the process recipe functions as a program that causes the controller 280 to execute respective processes in a substrate processing operation (which will be described later) to obtain a predetermined result. Hereinafter, the process recipe and the control program are collectively referred to as a program. Also, the term “program” used herein may include only one or both of the process recipe and the control program.

The CPU 281, the ROM 282, the RAM 283, the HDD 284, the display driver 287, the operation input detecting unit 289, and the communication I/F unit 285 are connected to each other through a system bus 286. Thus, the CPU 281 may access the ROM 282, the RAM 283, and the HDD 284, control the display of various information on the display 288 through the display driver 287, detect operation information from the display 288, and control the communication of various information with the respective members through the communication I/F unit 285. Also, the CPU 281 may detect an operation state of a user on the operation input unit 290 through the operation input detecting unit 289.

The temperature control unit 291 includes: a heater 207; a heating power supply 250 that supplies power to the heater 207; a temperature sensor 263; a communication I/F unit 293 that communicates various information such as set temperature information with the controller 280; and a heater control unit 292 that controls the power supply from the heating power supply 250 to the heater 207 based on the received set temperature information and the temperature information from the temperature sensor 263. The heater control unit 292 may be implemented by a computer. The communication I/F unit 293 of the temperature control unit 291 and the communication I/F unit 285 of the controller 280 are connected through a cable 751.

The pressure control unit 294 includes: an APC valve 243; a pressure sensor 245; a communication I/F unit 296 that communicates various information, such as set pressure information and open/close information of the APC valve 243, with the controller 280; and an APC valve control unit 295 that controls the opening/closing or the opening degree of the APC valve 243 based on the received set pressure information, the open/close information of the APC valve 243, and the pressure information from the pressure sensor 245. The APC valve control unit 295 may also be implemented by a computer. The communication I/F unit 296 of the pressure control unit 294 and the communication I/F unit 285 of the controller 280 are connected by a cable 752.

The vacuum pump 246, the boat rotation mechanism 267, the boat elevator 115, the mass flow controllers 312, 322, 512 and 522, the vaporizer 315, the RF power supply 270, and the communication I/F unit 285 of the controller 280 are connected by cables 753, 754, 755, 756, 757, 758, 759, 760 and 762, respectively.

The valve control unit 299 includes: valves (air valves) 314, 323, 513, 523, 612 and 622; and a magnetic valve group 298 that controls the supply of air to the valves 314, 323, 513, 523, 612 and 622. The magnetic valve group 298 includes magnetic valves 297 corresponding respectively to the valves 314, 323, 513, 523, 612 and 622. The magnetic valve group 298 and the communication I/F unit 285 of the controller 280 are connected by a cable 763.

In this manner, the respective members, such as the mass flow controllers 312, 322, 512 and 522, the valves 314, 323, 513, 523, 612 and 622, the APC valve 243, the vaporizer 315, the heating power supply 250, the temperature sensor 263, the pressure sensor 245, the vacuum pump 246, the boat rotation mechanism 267, the boat elevator 115, and the RF power supply 270 are connected to the controller 280. The controller 280 performs: a flow control of the mass flow controllers 312, 322, 512 and 522; an open/close operation control of the valves 314, 323, 513, 523, 612 and 622; an open/close operation control of the APC valve 243; a pressure control through an opening degree control operation based on the pressure information from the pressure sensor 245; a temperature control through a vaporization operation of the vaporizer 315 and a control operation of power supply from the heating power supply 250 to the heater 207 based on the temperature information from the temperature sensor 263; a control of RF power supplied from the RF power supply 270; a control of the activation/deactivation of the vacuum pump 246; a control of the speed of the rotation of the boat by the boat rotation mechanism 267; and a control of the elevation of the boat by the boat elevator 115.

Also, the controller 280 is not limited to being configured by a dedicated computer, and may be configured by a general-purpose computer. For example, the controller 280 according to this embodiment may be configured by preparing an external memory device (for example, a magnetic tape, a magnetic disk such as a flexible disk or a hard disk, an optical disk such as a compact disk (CD) or a digital versatile disk (DVD), a magneto-optical disk such as MO, and a semiconductor memory such as a USB memory or a memory card) storing the above program, and installing the program in a general-purpose computer by using the external memory device. Also, the unit for supplying the program to the computer is not limited to the external memory device. For example, without using the external memory device, the program may be supplied to the computer by using a communication unit such as the Internet or a dedicated line. Also, the memory device or the external memory device may be configured as a computer-readable recording medium. Hereinafter, they are collectively referred to as a recording medium. Also, the term “recording medium” used herein may include only one or both of the memory device and the external memory device.

Next, a description will be given of an example of a semiconductor device manufacturing process for manufacturing a large-scale integrated (LSI) circuit by using the above substrate processing apparatus. Also, in the following description, the operations of the respective members of the substrate processing apparatus are controlled by the controller 280. Herein, a thin film is deposited on a wafer 200 by continuously supplying at least one of a plurality of types process gases to the wafer 200 while heating the temperature inside a process chamber to a first temperature; and intermittently supplying at least one type of process gas different from the continuously-supplied process gas to the wafer 200. That is, a thin film is deposited on the wafer 200 by performing a process of simultaneously supplying a plurality of types of process gases to the wafer 200, and a process of supplying a process gas other than at least one of the plurality of types of process gases to the wafer 200. The intermittent supply of at least one type of process gas different from the continuously-supplied process gas to the wafer 200 may be repeated a predetermined number of times, and the flow of the continuously-supplied process gas may be changed in a partial interval during the repetition. Also, a stress-controlled low-resistance film is formed by performing a stress control process of control a stress by generating a migration of film composition atoms by supplying plasma energy to the film deposited on the wafer 200 while dropping the temperature inside the process chamber. The temperature inside the process chamber at the termination of the stress control process is referred to as a second temperature.

Hereinafter, a description will be given of an example of forming a titanium nitride (TiN) film as a metal film or a metal nitride film on a wafer 200 as a substrate by using the substrate processing apparatus. Also, herein, the term “metal film” represents a film formed of a conductive material containing metal atoms, and includes a conductive metal nitride film, a conductive metal oxide film, a conductive metal oxynitride film, a conductive metal compound film, a conductive metal alloy film, a conductive metal silicide film, a conductive metal carbide film, and a conductive metal carbonitride film, as well as a conductive metal film. Also, for example, the conductive metal nitride film is a titanium nitride film, the conductive metal carbonitride film is a titanium carbonitride film, and the conductive metal carbide film is a titanium carbide film.

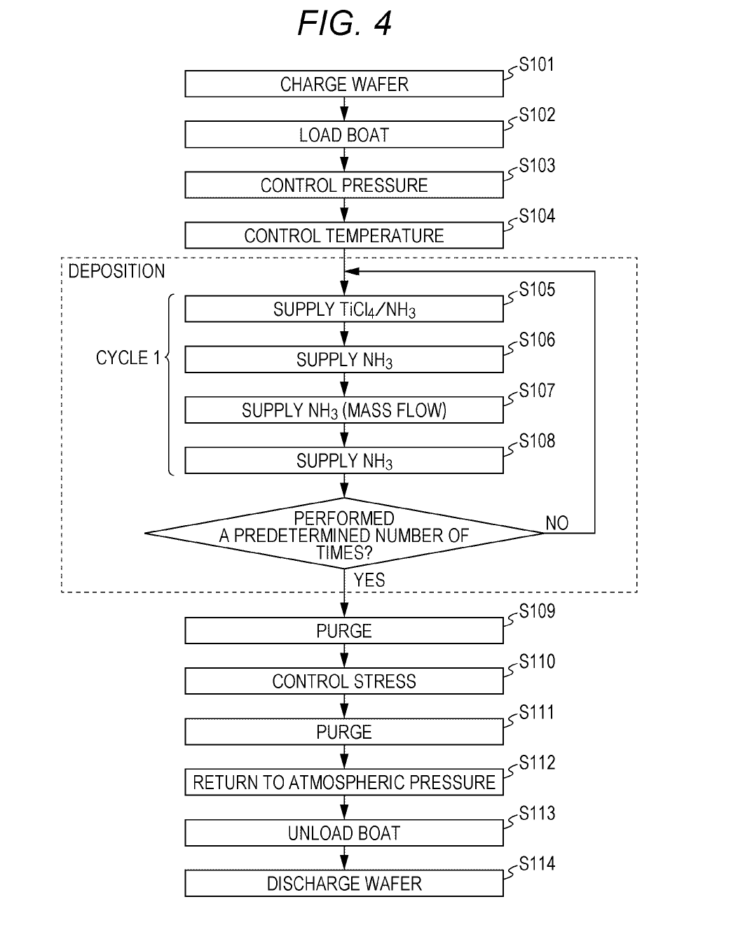

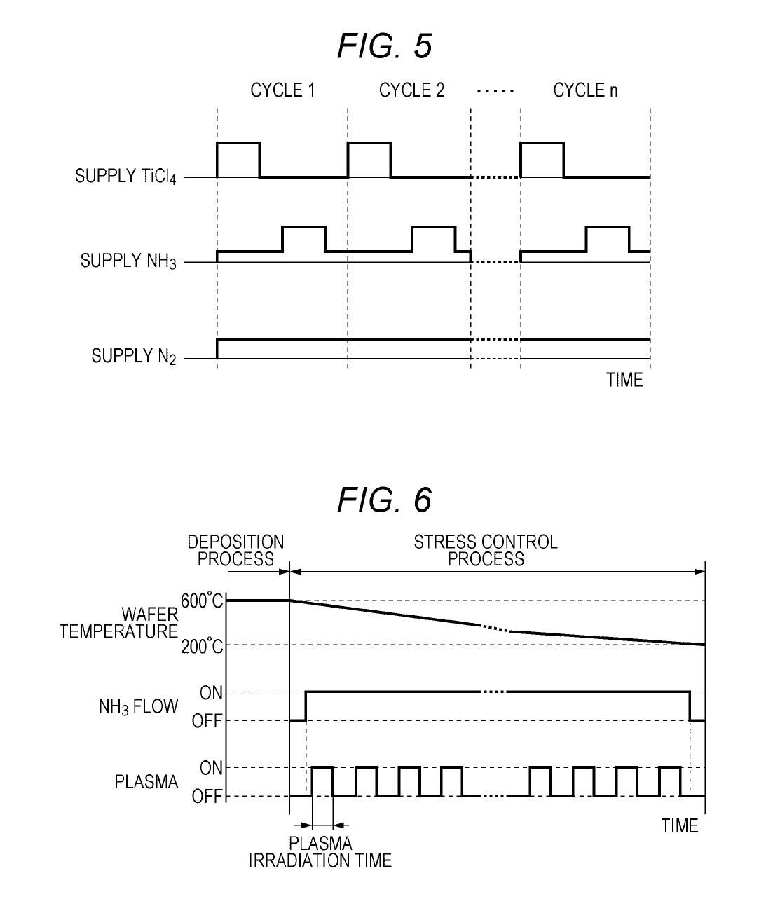

Herein, with reference to FIGS. 4 and 5, a description will be given of an example in which a first element is titanium (Ti); a second element is nitrogen (N); TiCl₄ that is a Ti-containing raw material as a metal-containing raw material is used as a raw material containing the first element; NH₃ that is a N-containing gas is used as a reaction gas containing the second element; and a TiN film is formed on a wafer 200 (for example, a surface of the wafer 200, or an underlayer formed on the surface). FIG. 4 is a flow chart illustrating a TiN film manufacturing process. FIG. 5 is a timing chart illustrating a TiN film manufacturing process.

### (Substrate Charging Process S101)

A plurality of (for example, 100) wafers 200 is charged into the boat 217 (wafer charging).

### (Substrate Loading Process S102)

Subsequently, a furnace port shutter (not illustrated) is opened. The boat 217 supporting the plurality of wafers 200 is elevated by the boat elevator 115 and loaded into the process chamber 201 (boat loading). In this state, the seal cap 219 seals the bottom end of the reaction tube 203 through the O-ring 220. Thereafter, the boat 217 is rotated by the boat rotation mechanism 267 to rotate the wafers 200.

### (Pressure Control Process S103, Temperature Control Process S104)

Thereafter, the vacuum pump 246 is activated. The APC valve 243 is opened to vacuumize the inside of the process chamber 201 to a desired pressure (vacuum degree) by the vacuum pump 246, and the heating power supply 250 supplying power to the heater 207 is controlled to raise the temperature inside the process chamber 201 to a first temperature ranging from 600° C. to about 650° C., for example, 600° C. When the temperature of the wafers 200 reaches 600° C. and the temperature and the like are stabilized, subsequent steps are sequentially executed while maintaining the temperature inside the process chamber 201 at 600° C. In this case, the pressure inside the process chamber 201 is measured by the pressure sensor 245, and the opening degree of the APC valve 244 is feedback-controlled based on the measured pressure (pressure control). Also, the inside of the process chamber 201 is heated to a desired temperature by the heater 207. In this case, in order to maintain the temperature inside the process chamber 201 at a desired temperature, the state of power supply from the heating power supply 250 to the heater 207 is feedback-controlled based on the temperature information measured by the temperature sensor 263 (temperature control).

Also, in parallel with processes S101 to S104, a liquid raw material TiCl₄ is vaporized to generate a TiCl₄ gas (preliminary vaporization). That is, a TiCl₄ gas is pre-generated by supplying TiCl₄ into the vaporizer 315 while controlling a flow rate thereof by the mass flow controller 312 by opening the valve 612 with the valve 314 closed. In this case, while activating the vacuum pump 246, by opening the valve 612 with the valve 314 closed, without supplying a TiCl₄ gas into the process chamber 201, the process chamber 201 is bypassed and exhausted. As described above, by pre-generating a TiCl₄ gas for stable supply thereof and switching the opening/closing of the valves 314 and 612, a flow path of the a TiCl₄ gas is switched. Accordingly, the start/stop of supply of the TiCl₄ gas into the process chamber 201 can be performed stably and rapidly.

Subsequently, a TiN film forming process of depositing a TiN film on the wafers 200 by supplying the TiCl₄ gas and the NH₃ gas into the process chamber 201 is performed. In the TiN film forming process, the following four steps (steps 105 to 108) are sequentially executed.

### (TiN Film Forming Process)

### (TiCl₄/NH₃ Supply Process S105)

In a TiCl₄/NH₃ supply process S105, a TiCl₄ gas as a Ti-containing gas is supplied from the gas supply pipe 310 of the gas supply system 301 through the gas supply hole 411 of the nozzle 410 into the process chamber 201. Specifically, by closing the valve 612 and opening the valves 314 and 513, together with a carrier gas (N₂), a TiCl₄ gas generated by vaporization in the vaporizer 315 is supplied from the gas supply pipe 310 into the process chamber 201. The carrier gas (N₂) is supplied from the gas supply pipe 510. The flow rate of the carrier gas (N₂) is controlled by the mass flow controller 512. The TiCl₄ gas is merged and mixed with the carrier gas (N₂) at the downstream side of the valve 314, and is supplied through the nozzle 410 into the process chamber 201.

Also, NH₃ is supplied from the gas supply pipe 320 of the gas supply system 302 through the gas supply hole 421 of the nozzle 420 into the buffer chamber 423. NH₃ is flow-controlled by the mass flow controller 322 and is supplied from the gas supply pipe 320 into the buffer chamber 423. Before being supplied into the buffer chamber 423, NH₃ is flowed through the valve 622 into the vent line 620 by closing the valve 323 and opening the valve 622. When NH₃ is supplied to the buffer chamber 423, the valve 622 is closed and the valve 323 is opened to supply NH₃ to the gas supply pipe 320 downstream of the valve 323, and the valve 523 is opened to supply the carrier gas (N₂) from the carrier gas supply pipe 520. The flow rate of the carrier gas (N₂) is controlled by the mass flow controller 522. NH₃ is merged and mixed with the carrier gas (N₂) at the downstream side of the valve 323, and is supplied through the nozzle 420 into the buffer chamber 423.

At this time, the opening degree of the APC valve 243 is controlled to maintain the pressure inside the process chamber 201 within a range of 10 Pa to 30 Pa, for example, at 30 Pa. The supply flow rate of the TiCl₄ gas may be within a range of 1 g/min to 3 g/min, preferably 2 g/min, and the supply flow rate of the NH₃ gas may be, for example, within a range of 0.5 slm to 1 slm, preferably 0.5 slm (first flow rate). The time for simultaneously supplying the TiCl₄ gas and the NH₃ gas to the wafers 200 (the time for simultaneously exposing the wafer 200 to the TiCl₄ gas and the NH₃ gas) may be, for example, within a range of 5 seconds to 20 seconds, preferably 10 seconds.

The TiCl₄ gas and the NH₃ gas supplied into the process chamber 201 are supplied to the wafers 200 and are exhausted from the exhaust pipe 231. At this time, the TiCl₄ gas and the NH₃ gas react together to form a TiN layer on the wafers 200. After the lapse of a predetermined time, the valve 314 is closed and the valve 612 is opened to stop the supply of the TiCl₄ gas.

### (NH₃ Supply Process S106)

After the valve 314 is closed to stop the supply of the TiCl₄ gas into the process chamber 201, the HH₃ gas is continuously flowed for a predetermined time at a flow rate that is equal to or lower than the first flow rate in the TiCl₄/NH₃ supply process S105. The NH₃ gas supplied into the process chamber 201 is supplied to the TiN layer on the wafers 200 and are exhausted from the exhaust pipe 231. By supplying the NH₃ gas, the reaction products or the TiCl₄ gas left in the process chamber 201 can be eliminated, and a chlorine (Cl) component (chloride) left in the TiN layer by reacting with the TiN layer on the wafers 200 can be removed.

At this time, when the valve 513 is opened to flow N₂ (inert gas) from the carrier gas supply pipe 510 connected in the middle of the gas supply pipe 310, it is possible to prevent the NH₃ gas from returning into the gas supply pipe 310 or the nozzle 410 of the TiCl₄ side. Also, since the NH₃ gas is prevented from returning thereinto, the flow rate of N₂ (inert gas) controlled by the mass flow controller 512 may be small.

### (NH₃ Gas Supply Process S107)

Subsequently, the flow rate is controlled by the mass flow controller 322 such that the flow rate of the NH₃ gas is higher than that in NH₃ supply process S106 (second flow rate). At this time, the opening degree of the APC valve 243 is controlled to maintain the pressure inside the process chamber 201 within a range of 70 Pa to 1,000 Pa, for example, at 70 Pa. The supply flow rate of the NH₃ gas may be, for example, within a range of 5 slm to 10 slm, preferably 7.5 slm. The time for supplying the NH₃ gas to the wafers 200 (the time for exposing the wafer 200 to the NH₃ gas) may be, for example, within a range of 30 seconds to 60 seconds, preferably 35 seconds.

The NH₃ gas supplied into the process chamber 201 is supplied to the TiN layer on the wafers 200 and are exhausted from the exhaust pipe 231. At this time, only inert gases such as a NH₃ gas and a N₂ gas exist in the process chamber 201, and no Ti-containing gas such as a TiCl₄ gas exists in the process chamber 201. The NH₃ gas supplied into the process chamber 201 reacts with a non-reacted Ti-containing material existing on the wafers 200 to form a TiN layer, and reacts with a Cl component (Chloride) left between the TiN layers to remove Cl or HCl from the TiN layer.

Simultaneously, when the valve 513 is opened to flow a N₂ gas (inert gas) from the carrier gas supply pipe 510 connected in the middle of the gas supply pipe 310, it is possible to prevent NH₃ from returning into the gas supply pipe 310 or the nozzle 410 of the TiCl₄ side. Also, since NH₃ is prevented from returning thereinto, the flow rate of N₂ (inert gas) controlled by the mass flow controller 512 may be small.

### (NH₃ Gas Supply Process S108)

Subsequently, the flow rate is controlled by the mass flow controller 322 such that the flow rate of the NH₃ gas is lower than or equal to that in NH₃ gas supply process S107. At this time, the opening degree of the APC valve 243 is control to maintain the pressure inside the process chamber 201 at a predetermined pressure.

A cycle of processes S105 to S108 is performed at least one time to deposit a TiN film with a predetermined thickness on the wafers 200.

### (Purge Process S109)

After completion of the deposition process of forming the TiN film with a predetermined thickness, the valve 323 is closed, and the valve 622 is opened to stop the supply of NH₃. Also, the inside of the process chamber 201 is purged with the inert gas (N₂) by exhausting the inside of the process chamber 201 by the vacuum pump 246 with the APC valve 243 of the gas supply pipe 231 opened, while supplying the inert gas (N₂) into the process chamber 201 from the carrier gas supply pipe 510 and the carrier gas supply pipe 520. At this time, the gas left in the process chamber 201 may not be completely eliminated, and the inside of the process chamber 201 may not be completely purged. When the amount of gas left in the process chamber 201 is very small, it exerts no bad influence on a stress control process S110 that is subsequently performed. At this time, the flow rate of the N₂ gas supplied into the process chamber 201 may not be high. For example, by supplying the N₂ gas of the amount equal to the capacity of the reaction tube 203 (process chamber 201), a purge exerting no bad influence on the stress control process S110 may be performed. In this manner, since the inside of the process chamber 201 may not be completely purged, the purge time can be reduced and the throughput can be improved. Also, the N₂ gas consumption can be suppressed to a minimum.

### (Stress Control Process S110)

Subsequently, while dropping the temperature of the wafers 200, NH₃ plasma is irradiated onto the TiN film to control the stress of the TiN film. A stress control process S110 will be described with reference to FIG. 6.

After the residual gas inside the process chamber 201 is removed by the purge process S109, the temperature of the wafers 200 is dropped from the TiN film deposition temperature corresponding to the first temperature (in this embodiment, for example, 600° C.) to a second temperature (for example, 200° C.) different from the first temperature, at a predetermined temperature drop rate. The final temperature of the wafers 200 is selected properly in consideration of the throughput. The temperature drop rate may be, for example, within a range of 0.5° C./min to 5° C./min, preferably 0.5° C./min. When the temperature drop rate is low, the total plasma processing time may be long. On the other hand, when the temperature drop rate is high, the throughput is high but the total plasma processing time is short.

After the lapse of a predetermined time from the start of the temperature drop of the wafers 200, NH₃ supply is started. Also, NH₃ is supplied from the gas supply pipe 320 of the gas supply system 302 through the gas supply hole 421 of the nozzle 420 into the buffer chamber 423. NH₃ is flow-controlled by the mass flow controller 322 and is supplied from the gas supply pipe 320 into the buffer chamber 423. The flow rate of NH₃ may be, for example, within a range of 1 slm to 7.5 slm, preferably 1 slm. Before being supplied into the buffer chamber 423, NH₃ is flowed through the valve 622 into the vent line 620 by closing the valve 323 and opening the valve 622. When NH₃ is supplied to the buffer chamber 423, the valve 622 is closed and the valve 323 is opened to supply NH₃ to the gas supply pipe 320 downstream of the valve 323.

When NH₃ is supplied to the buffer chamber 423, the APC valve 243 is properly controlled such that the pressure inside the process chamber 201 may be, for example, within a range of 60 Pa to 400 Pa, preferably 266 Pa.

At this time, RF power is periodically applied between the electrode 471 and the electrode 472 from the RF power supply 270 through the matcher 271. The applied power may be, for example, within a range of 200 W to 600 W, preferably 300 W. By periodically applying the RF power, the NH₃ supplied into the buffer chamber 423 is periodically plasma-excited. Plasma-excited NH₃ is supplied from the gas supply hole 425 into the process chamber 201 by a temporally separated pulse, is irradiated onto the TiN film on the wafers 200, and is then exhausted from the exhaust pipe 231. The 1-cycle irradiation time of plasma-excited NH₃ may be, for example, 30 seconds or more, preferably 30 seconds. The 1-cycle irradiation time may be as long as possible. However, the 1-cycle irradiation time is too long, the temperature of the wafers 200 is raised by plasma irradiation. Therefore, the 1-cycle irradiation time is determined properly in consideration of this effect. The number of plasma irradiation cycles may be, for example, within a range of 80 to 800, preferably 400. The number of plasma irradiation cycles is determined properly in consideration of the throughput. Also, the number of plasma irradiation cycles is determined depending on the deposition process temperature, the final substrate temperature, and the temperature drop rate. Also, a predetermined time is given between the start of the flowing of NH₃ and the start of plasma irradiation. This is to stabilize plasma.

After the lapse of a predetermined time from the completion of plasma irradiation a predetermined number of times, NH₃ supply is stopped. The valve 323 is closed to stop the supply of NH₃ from the gas supply pipe 320 through the buffer chamber 423 to the process chamber 201, and the valve 622 is opened to flow NH₃ through the valve 622 to the vent line 620.

After the lapse of a predetermined time from the stop of NH₃ supply to the process chamber 201, when the temperature of the wafers 200 becomes 200° C., the stress control process is ended.

### (Purge Process S111)

After completion of the stress control process, the inside of the process chamber 201 is purged with the inert gas (N₂) by exhausting the inside of the process chamber 201 by the vacuum pump 246 with the APC valve 243 of the gas supply pipe 231 opened, while supplying the inert gas (N₂) into the process chamber 201 from the carrier gas supply pipe 510 and the carrier gas supply pipe 520.

### (Atmospheric Pressure Returning Process S112)

Thereafter, the inside of the process chamber 201 is filled with atmospheric inert gas (N₂), and thus the pressure inside the process chamber 201 returns to the atmospheric pressure.

### (Boat Unloading Process S113)

Thereafter, by lowering the seal cap 219 by the boat elevator 115, the lower end of the reaction tube 203 is opened, and the processed wafers 200 supported by the boat 217 are unloaded from the reaction tube 203 to the outside of the reaction tube 203 (boat unloading).

### (Wafer Discharging Process S114)

Thereafter, the processed wafers 200 are ejected from the boat 217.

As described above, by depositing the TiN film at a temperature of 600° C. or more, since the particle diameter of the TiN film increases and the concentration of impurities such as Cl decreases, the manufactured TiN film has a low electric resistance. FIG. 9 is a diagram illustrating a relation between the deposition temperature and the resistivity of the TiN film. The resistivity is less than 100 μΩcm at 600° C. or more, and is substantially constant at 650° C. or more.

FIG. 8 is a diagram illustrating a tensile stress value of the manufactured TiN film in a case where the stress control process S110 is provided and a tensile stress value in case where the stress control process S110 is not provided. As for the deposition conditions, the TiN film was formed when the temperature of the wafers 200 was 600° C., and NH₃ plasma was irradiated for 30 seconds×400 times while dropping the temperature of the wafers 200 to 200° C. at a rate of 0.5° C./min. Referring to FIG. 8, it can be seen that the TiN film with a low tensile stress could be manufactured by providing the stress control process S110. Also, this data is obtained by calculation from a change in the substrate warpage amount before/after the TiN film deposition.

In order to obtain a low-resistance film, it may be preferable to perform the deposition process at a high temperature. However, when the wafers 200 in a high-temperature state are ejected by boat unloading, they may be oxidized. Therefore, it may be preferable to drop the temperature of the wafers 200 before ejecting the wafers 200. Since a film is formed on a high-temperature and thermally-expanded wafer 200 during the deposition and the wafer 200 and the film have different thermal expansion coefficients, a film stress is generated during the temperature drop. While dropping the temperature of the wafer 200 in the stress control process S110, by providing NH₃ plasma energy to the TiN film formed in the deposition process, a migration of atoms constituting the TiN film is generated, and the TiN film having a film stress changed by the stress control is obtained. That is, since NH₃ plasma is irradiated onto the TiN film formed in the deposition process while dropping the temperature of the wafer 200 in the stress control process S110, a lattice distortion caused by a thermal expansion coefficient difference in the thermal contraction of the wafer 200 and the TiN film is reduced by moving Ti and N atoms to stable positions by NH₃ plasma irradiation, thereby changing the film stress.

In this manner, since plasma is provided in a temperature-dropping state having heat, a migration of the Ti and N atoms is performed to reduce the stress. Thus, even in the case of performing rapid cooling by a high temperature drop rate and performing the plasma process after stabilization at a low temperature, the stress cannot be reduced.

Since NH₃ plasma is irradiated onto the TiN film while dropping the temperature of the wafer 200 in the stress control process S110, the stress of the TiN film can be reduced even without providing post-processing after the deposition. Therefore, a throughput degradation caused by the provision of the stress control process S110 can be prevented or suppressed.

In order to obtain a low-resistance film, it may be preferable to perform the deposition process at a high temperature. Accordingly, when considering the productivity, it may be preferable that the deposition method including the stress control process is performed by a vertical batch apparatus as in this embodiment.

The high film stress increases a film peeling-off, a film crack, or a wafer warpage, thus causing a degradation of the electrical characteristics of a semiconductor device, a reliability degradation, a production yield degradation, and a throughput degradation. However, in the present embodiment, since the film stress can be reduced by the stress control process S110, a film peeling-off, a film crack, or a wafer warpage can be reduced, thus making it possible to improve the electrical characteristics of a semiconductor device or the reliability thereof and improve the production yield or the throughput.

As described above, according to the present embodiment, a low-resistance TiN film can be obtained by stress control. The final TiN film has a thickness of, for example, 5 nm to 30 nm, preferably 15 nm. Up to 30 nm, plasma can arrive in the depth direction. Also, the resistivity is 80 μΩcm or less, and the tensile stress is 1.6 GPa or less.

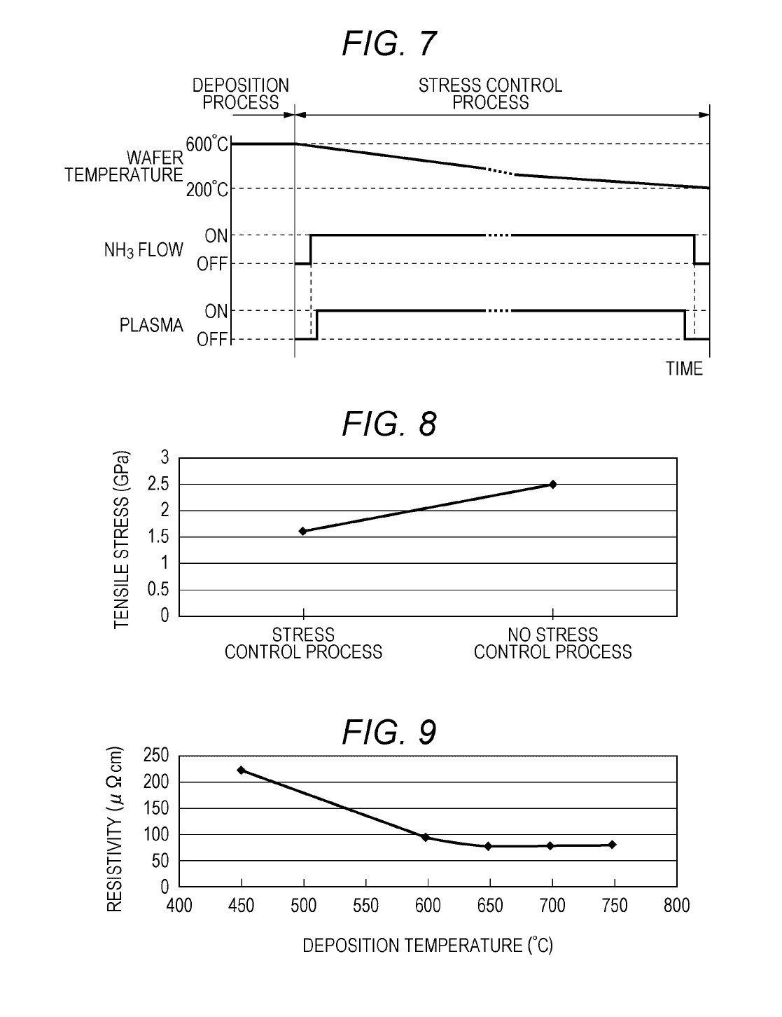

In the present embodiment, NH₃ plasma is cyclically irradiated as illustrated in FIG. 6; however, the present invention is not limited thereto. NH₃ plasma may be continuously irradiated as illustrated in FIG. 7. In the case of cyclical irradiation, an activation region in the depth direction can be controlled, but a stress control process per unit time is shortened and thus the total time is increased. On the other hand, in the case of continuous irradiation, a stress control process per unit time can be increased and thus the throughput can be improved. However, when plasma is continuously irradiated, the temperature of the wafers 200 is raised, the temperature of the wafers 200 may not be dropped at a desired rate.

Also, in the present embodiment, NH₃ plasma is irradiated while dropping the temperature; however, the present invention is not limited thereto. The film stress may also be controlled by irradiating NH₃ plasma while raising the temperature.

In the above embodiment, NH₃ plasma is irradiated in the stress control process S110. However, NH₃, heavy rare gases (such as neon (Ne) and argon (Ar)), N₂, and all NH₃ plasmas may be applicable, and NH₃ and rare gases such as Ne and Ar may be preferable. When NH₃ is used, a low-resistance film can be obtained by reducing the Cl amount in the film. In order to provide energy to atoms in the film, heavy rare gases (such as Ne and Ar) may be preferable. N₂ may also be applicable.

Also, a method of exciting atoms forming the TiN film or the gas may be microwave excitation or light excitation, in addition to plasma discharge excitation.

Also, the TiN film may be plasma-processed, microwave-processed, or light-processed by inert gases such as Ar, helium (He), and xenon (Xe).

Also, the TiN film may be plasma-processed, microwave-processed, or light-processed by gases containing nitrogen atoms, such as N₂ and mono methyl hydrazine.

Also, the TiN film may be plasma-processed, microwave-processed, or light-processed by N₂ as a gas containing nitrogen atoms, in addition to NH₃.

In the above embodiment, the stress of the TiN film is controlled; however, any metal-containing film may be applicable. A pure metal or metal compound film may be applicable, and for example, a tungsten (W) film may also be applicable.

Also, a metal-containing gas used to form a metal-containing film may include an inorganic metal compound or an organic metal compound.

Also, while plasma is used in the deposition, the stress control process of the present embodiment may be applicable in the case of non-plasma. The use or not of plasma in the deposition does not affect the subsequent stress control process.

In the deposition, the TiN layer may be annealed, plasma-processed, microwave-processed, or light-processed by using Ar, He, or Xe as an inert gas. Also, in the deposition, the TiN layer may be annealed, plasma-processed, microwave-processed, or light-processed by using N₂, NH₃, mono methyl hydrazine as a gas containing nitrogen atoms. Also, in the deposition, the TiN layer may be annealed, plasma-processed, microwave-processed, or light-processed by a gas containing hydrogen atoms, such as a hydrogen gas.

Also, the metal-containing film may be used as an electrode material for a metal oxide semiconductor (MOS) transistor.

In this case, the electrode material for a MOS transistor may be formed on a three-dimensional underlayer.

Also, the metal-containing film may be used as a bottom or top electrode material for a capacitor.

Also, the metal-containing film may be used as a buried word line for a dynamic random access memory (DRAM).

Also, the above embodiment illustrates an exemplary case of depositing a thin film by using a batch-type substrate processing apparatus that simultaneously processes a plurality of substrates; however, the present invention is not limited thereto. The present invention may also be applicable to a case of depositing a thin film by using a single-type substrate processing apparatus that processes one or several substrates at a time.

Also, the respective deposition sequences of the above embodiment, modifications, and applications may be used in combination.

Also, the present invention may also be implemented, for example, by changing the process recipe of the conventional substrate processing apparatus. The process recipe may be changed by installing a process recipe according to the present invention in the conventional substrate processing apparatus through an electric communication line or a recording medium storing the process recipe. Also, the process recipe may be changed into the process recipe according to the present invention by operating an input/output device of the conventional substrate processing apparatus.

### EXEMPLARY ASPECTS OF THE PRESENT INVENTION

Hereinafter, exemplary aspects of the present invention will be supplementarily noted.

### (Supplementary Note 1)

According to an exemplary aspect of the present invention, there is provided a method of a manufacturing a semiconductor device including:

forming a film on a substrate by supplying a process gas to the substrate while heating the substrate to a first temperature; and

controlling a stress to change a stress value of the film formed on the substrate, by supplying a plasma-excited process gas to the substrate while changing a temperature of the substrate to a second temperature different from the first temperature.

### (Supplementary Note 2)

In the method of Supplementary Note 1, the film may be a metal-containing film.

### (Supplementary Note 3)

In the method of Supplementary Note 2, the film may be a titanium nitride (TiN) film.

### (Supplementary Note 4)

In the method of Supplementary Note 1, the second temperature may be lower than the first temperature.

### (Supplementary Note 5)

In the method of Supplementary Note 4, the first temperature may be 600° C. or more.

### (Supplementary Note 6)

In the method of Supplementary Note 4, the second temperature may be 200° C. or more.

### (Supplementary Note 7)

In the method of Supplementary Note 1, the plasma-excited process gas may be supplied by a temporally separated pulse in the act of controlling the stress.

### (Supplementary Note 8)

In the method of Supplementary Note 1, the plasma-excited process gas may be continuously supplied in the act of controlling the stress.

### (Supplementary Note 9)

In the method of Supplementary Note 1, the plasma-excited process gas may start to be supplied in the act of controlling the stress after a predetermined time from when the temperature of the substrate starts to be changed from the first temperature.

### (Supplementary Note 10)

In the method of Supplementary Note 1, the film after the act of controlling the stress may have a resistivity of 80 μΩcm or less and a stress of 1.6 GPa or less.

### (Supplementary Note 11)

In the method of Supplementary Note 1, at least one type of process gas may be used in the act of forming the film, and the at least one type of process gas may be identical to the process gas used in the act of controlling the stress.

### (Supplementary Note 12)

In the method of Supplementary Note 11, the process gas used in the act of controlling the stress may be ammonia (NH₃).

### (Supplementary Note 13)

In the method of Supplementary Note 1, the process gas used in the act of controlling the stress may be a rare gas.

### (Supplementary Note 14)

According to another exemplary aspect of the present invention, there is provided a method of manufacturing a semiconductor device including:

forming a film on a substrate by supplying a first process gas and a second process gas, wherein the second process gas is supplied by temporally separated pulse while the first process gas is supplied; and

controlling a stress to change a stress value of the film formed on the substrate.

### (Supplementary Note 15)

In the method of Supplementary Note 14, the substrate may be heated to a first temperature in the act of forming the film, and the temperature of the substrate may be changed from the first temperature to a second temperature in the act of controlling the stress.

### (Supplementary Note 16)

In the method of Supplementary Note 15, a third process gas may be supplied to the substrate in the act of controlling the stress while being plasma-excited.

### (Supplementary Note 17)

In the method of Supplementary Note 16, the first process gas and the third process gas may be identical to each other.

### (Supplementary Note 18)

In the method of Supplementary Note 16, the film may be a TiN film, and the first process gas and the third process gas may be ammonia (NH₃).

### (Supplementary Note 19)

In the method of Supplementary Note 16, the first process gas and the third process gas may be different from each other.

### (Supplementary Note 20)

In the method of Supplementary Note 19, the third process gas is a rare gas.

### (Supplementary Note 21)

In the method of Supplementary Note 14, the first temperature may be 600° C. or more, and the second temperature may be 200° C. or more.

### (Supplementary Note 22)

In the method of Supplementary Note 14, a plasma-excited process gas may be supplied by a temporally separated pulse in the act of controlling the stress.

### (Supplementary Note 23)

In the method of Supplementary Note 14, a plasma-excited process gas may be continuously supplied in the act of controlling the stress.

### (Supplementary Note 24)

In the method of Supplementary Note 14, a plasma-excited process gas may start to be supplied in the act of controlling the stress after a predetermined time from when the temperature of the substrate starts to be changed from the first temperature.

### (Supplementary Note 25)

In the method of Supplementary Note 14, the film after the act of controlling the stress may have a resistivity of 80 μΩcm or less and a stress of 1.6 GPa or less.

### (Supplementary Note 26)

According to another exemplary aspect of the present invention, there is provided a substrate processing method including:

forming a film on a substrate by supplying a process gas to the substrate while heating the substrate to a first temperature; and

controlling a stress to change a stress value of the film formed on the substrate, by supplying a plasma-excited process gas to the substrate while changing a temperature of the substrate to a second temperature different from the first temperature.

### (Supplementary Note 27)

According to another exemplary aspect of the present invention, there is provided a substrate processing apparatus including:

a process chamber configured to accommodate a substrate;

a heating system configured to heat the substrate;

a process gas supply system configured to a plurality of types of process gases to the substrate;

a plasma generating system configured to generate plasma for plasma-exciting at least one of the plurality of types of process gases; and

a control unit configured to control the heating system, the process gas supply system, and the plasma generating system to form a film on the substrate by supplying a plurality of types of process gases to the process chamber while heating the substrate to a first temperature, and to control a stress to change a stress value of the film by supplying a plasma-excited process gas to the substrate while changing a temperature of the substrate from the first temperature to a second temperature.

### (Supplementary Note 28)

According to another exemplary aspect of the present invention, there is provided a film depositing method that forms a pure metal or metal compound film on a process target substrate, in which a conductor film, an insulating film, or a conductor pattern insulated by an insulating film is exposed, by reacting any one of an inorganic metal compound or an organic metal compound against a reactive gas having a reactivity with respect to a metal compound,

wherein the film depositing method supplies energy to the formed film by a method other than a resistance heater, such as plasma irradiation, microwave irradiation, or light irradiation, while thermally contracting/expanding the process target substrate by changing a temperature of the process target substrate to a temperature different from a deposition temperature after the forming of the film, and generates a migration of film composition atoms, thereby forming a stress-controlled thin film on the process target substrate.

### (Supplementary Note 29)

In the film depositing method according to Supplementary Note 28, the inorganic metal compound or the organic metal compound may contain titanium (Ti), the reactive gas may contain nitrogen (N), and the formed thin film may be a titanium nitride (TiN)-containing film.

### (Supplementary Note 30)

In the film depositing method according to Supplementary Note 28 or 29, the inorganic metal compound may be a titanium tetrachloride (TiCl₄), the reactive gas may be ammonia (NH₃), and the formed thin film may be a TiN thin film.

### (Supplementary Note 31)

In the film depositing method according to any one of Supplementary Notes 28 to 30, the pure metal or metal compound film may be a gate electrode material for a metal oxide semiconductor (MOS) transistor.

### (Supplementary Note 32)

In the film depositing method according to Supplementary Note 31, the gate electrode material for the MOS transistor may be formed on a three-dimensional underlayer.

### (Supplementary Note 33)

In the film depositing method according to any one of Supplementary Notes 28 to 30, the pure metal or metal compound film may be a bottom or top electrode material for a capacitor.

### (Supplementary Note 34)

In the film depositing method according to any one of Supplementary Notes 28 to 30, the pure metal or metal compound film may be a buried word line for a dynamic random access memory (DRAM).

### (Supplementary Note 35)

In the film depositing method according to any one of Supplementary Notes 28 to 34, the film may be formed by using a batch furnace that can process a plurality of process target substrates simultaneously.

### (Supplementary Note 36)

In the film depositing method according to Supplementary Note 35, the batch furnace may be a vertical furnace that processes a vertical stack of a plurality of process target substrates, wherein an internal pipe having a diameter substantially identical to a diameter of the process target substrate may be provided inside a reaction tube thereof, and the gas may be introduced from the side between the process target substrates located inside the internal pipe.

### (Supplementary Note 37)

In the film depositing method according to any one of Supplementary Notes 28 to 36, a TiN film formed to a thickness of 15 nm at a temperature of 600° C. may be a conductive film having a resistivity of 80 μΩcm or less and a tensile stress of 1.6 GPa or less.

### (Supplementary Note 38)

According to another exemplary aspect of the present invention, there is provided a semiconductor device including a conductive film that is a conductive thin film deposited at a temperature of 600° C. or more, and has a resistivity of 80 μΩcm or less and a tensile stress of 1.6 GPa or less.

### (Supplementary Note 39)

According to another exemplary aspect of the present invention, there is provided a program for causing a computer to execute:

a film forming process of forming a film on a substrate inside a process chamber of a substrate processing apparatus by supplying a process gas to the substrate while heating the substrate to a first temperature; and

a stress control process of controlling a stress to change a stress value of the film formed on the substrate, by supplying a plasma-excited process gas to the substrate while changing a temperature of the substrate to a second temperature different from the first temperature.

### (Supplementary Note 40)

According to another exemplary aspect of the present invention, there is provided a computer-readable recording medium storing the program according to Supplementary Note 39.

### (Supplementary Note 41)

According to another exemplary aspect of the present invention, there is provided a substrate processing apparatus including the computer-readable recording medium according to Supplementary Note 40.

While the exemplary embodiments of the present invention have been described above, the present invention is not limited thereto. Therefore, the scope of the present invention is defined only by the following claims.

1. A method of manufacturing a semiconductor device comprising:
forming a film on a substrate by supplying a process gas to the substrate while heating the substrate to a first temperature; and
controlling stress to the film by changing a stress value of the film, by supplying a plasma-excited process gas to the substrate while changing a temperature of the substrate to a second temperature different from the first temperature.

2. The method of claim 1, wherein the film is a metal-containing film.

3. The method of claim 2, wherein the film is a titanium nitride film.

4. The method of claim 1, wherein the second temperature is lower than the first temperature.

5. The method of claim 4, wherein the first temperature is 600° C. or more.

6. The method of claim 4, wherein the second temperature is 200° C. or more.

7. The method of claim 1, wherein the plasma-excited process gas is supplied by a temporary pulse in the act of controlling the stress.

8. The method of claim 1, wherein the plasma-excited process gas is continuously supplied in the act of controlling the stress.

9. The method of claim 1, wherein the plasma-excited process gas starts to be supplied in the act of controlling the stress after a predetermined time from when the temperature of the substrate starts to change from the first temperature.

10. The method of claim 1, wherein the film after the act of controlling the stress has a resistivity of 80 μΩcm or less and a stress of 1.6 GPa or less.

11. The method of claim 1, wherein at least one type of process gas is used in the act of forming the film, and the at least one type of process gas is identical to the process gas used in the act of controlling the stress.

12. The method of claim 11, wherein the process gas used to control the stress is ammonia.

13. The method of claim 1, wherein the process gas used to control the stress is a rare gas.

14. A method of manufacturing a semiconductor device comprising:
forming a film on a substrate by supplying a first process gas and a second process gas, wherein the second process gas is supplied by temporary pulse while the first process gas is supplied; and
controlling a stress to the film by changing a stress value of the film.
